(19) United States
(12) Patent Application Publication
(10) Pub. No.: US 2012/0064645 A1
(43) Pub. Date: Mar. 15, 2012

(54) MANUFACTURING METHOD OF SEMICONDUCTOR DEVICE

(75) Inventors: Peter LEE, Tokyo (JP); Yasuhiro Nanba, Tokyo (JP)

(73) Assignee: Elpida Memory, Inc.

(21) Appl. No.: 13/214,810

(22) Filed: Aug. 22, 2011

(30) Foreign Application Priority Data
Sep. 10, 2010 (JP) 2010-203012

(51) Int. Cl. H01L 21/66

(52) U.S. Cl. 438/17; 257/E21.531

(57) ABSTRACT

A method for manufacturing a semiconductor device according to the present invention comprises: forming a semiconductor circuit including a first transistor with a first threshold voltage and a first drain-source current; applying a stress voltage to the first transistor to make at least one of a change from the first threshold voltage a second threshold voltage and a change from the first drain-source current to a second drain-source current; and shipping the semiconductor circuit while the first transistor is presenting one of the second threshold voltage and the second drain-source current.

### BACKGROUND OF THE INVENTION

1. Field of the Invention

The present invention relates to a manufacturing method of a semiconductor device and, more particularly, to a manufacturing method of a semiconductor device having a variety of transistors.

2. Description of Related Art

A manufacturing process of a semiconductor device can be roughly divided into two stages: a front-end process including a diffusion process and a wafer test process; and a back-end process including an assembly/finishing process and a test process. More in detail, the front-end process includes a process of depositing a thin film on a semiconductor substrate and patterning the thin film into a desired shape and a process of implanting impurities into the semiconductor or deposited thin film. With the front-end process finished, a wafer-state semiconductor device is completed. In the back-end process, dicing the wafer obtained through the front-end process into individual chips and packaging each of the individual chips are performed. In addition, a test of a packaged semiconductor device is performed. Semiconductor devices determined to be a non-defective product in this test are then shipped out.

Japanese Patent Application Laid-Open No. 07-262798 discloses a technique concerning a burn-in test which is a kind of a test performed in the back-end process. The burn-in test, which aims to previously find a part more likely to fail during normal operation after shipment, applies a test voltage to an internal circuit of a semiconductor device and detects a defect in the semiconductor device.

In recent semiconductor devices, the role of a transistor is diversified and, accordingly, values of a threshold voltage Vₜₕ and drain-source current I_{ds} required for the transistor are also diversified. Such diversified values are generally realized by changing the type or amount of impurities to be implanted into a channel region for each transistor in the front-end process.

However, a change in the type or amount of impurities in the front-end process for each transistor may cause an increase in manufacturing cost or manufacturing time. Thus, a countermeasure for suppressing manufacturing cost or manufacturing time is required.

Further, it is known that the absolute value of the threshold voltage Vₜₕ of the transistor or drain-source current I_{ds} gradually increases with age. Such a change in the value makes design of a semiconductor device difficult, so that a countermeasure for suppressing the change is also required.

### SUMMARY

In one embodiment, there is provided a method for manufacturing a semiconductor device, comprising: forming a semiconductor circuit including a first transistor designed with device parameters for allowing the first transistor to exhibit a first threshold voltage and a first drain-source current; applying a stress voltage to the first transistor so as to allow the first transistor to exhibit at least one of a second threshold voltage different from the first threshold voltage and a second drain-source current different from the first drain-source current; and shipping the semiconductor device with the first transistor exhibiting at least one of the second threshold voltage and second drain-source current.

In another embodiment, there is provided a method for manufacturing a semiconductor device comprising: forming a semiconductor circuit including first and second transistors designed to be the same in a certain characteristic; applying a first stress voltage to the first transistor so as to make the first and second transistors differ in the certain characteristic; and performing a burn-in test by applying a second stress voltage to both the first and second transistors.

According to the present invention, the characteristics of transistors into which impurities of the same type and the same amount are implanted at the channel part in the semiconductor circuit formation step can be made different from one another in the characteristic control step. This allows a reduction in the manufacturing cost and manufacturing time.

Further, applying the stress voltage for characteristic control corresponds to generation of pseudo aging change, so that it is possible to suppress the aging change after shipment by bringing the aging change to its saturated state.

### BRIEF DESCRIPTION OF THE DRAWINGS

The above and other features and advantages of the present invention will be more apparent from the following description of certain preferred embodiments taken in conjunction with the accompanying drawings, in which:

FIGS. 1A and 1B show an N-channel type MOS transistor and a P-channel type MOS transistor, respectively;

FIG. 2 is a graph plotting a change in a variation of the threshold voltage with respect to time in the case where 0.5 and 10⁻⁵ are assigned respectively to n and A;

FIG. 3 is a graph showing a concrete example of a change in the variation of the threshold voltage with respect to time;

FIGS. 4A and 4B are views each showing a process flow of the semiconductor device manufacturing method according to the present embodiment;

FIG. 5 is a graph showing the relationship between the drain-source voltage of a N-channel type MOS transistor and variation of its threshold voltage in the case where the application time period is set to 200 seconds;

FIG. 6 is a graph showing the relationship between the gate-source voltage of a P-channel type MOS transistor and variation of its threshold voltage in the case where the application time period is set to 200 seconds;

FIG. 7 is a view showing a circuit configuration of a semiconductor device corresponding to the semiconductor device manufacturing method according to the present embodiment;

FIG. 8 is a view showing a modified example of the semiconductor device corresponding to the semiconductor device manufacturing method according to the present embodiment;

FIG. 9 is a view showing another modified example of the semiconductor device corresponding to the semiconductor device manufacturing method according to the present embodiment;

FIG. 10 shows a circuit configuration of the semiconductor device having the plurality of semiconductor circuit corresponding to the semiconductor device manufacturing method according to the present embodiment;

FIG. 11 is a graph plotting an example of the temporal change of a normalized variation of the drain-source current indicated in equation (2);

FIG. 12 shows an example of the temporal change of the normalized variation of the drain-source current assuming that a typical operating voltage continues to be applied to the transistor;

FIG. 13 is a graph showing the relationship between the drain-source voltage and normalized variation of the drain-source current in the case where the application time period is set to 200 seconds for the N-channel type MOS transistor of FIG. 1A;

FIG. 14 is a graph showing the temporal change of the normalized variation of the drain-source current in the case where the drain-source voltage is set to 2.0 [V] for the N-channel type MOS transistor of FIG. 1A;

FIG. 15 is a graph showing the relationship between the gate-source voltage and normalized variation of the drain-source current in the case where the application time period is set to 200 seconds for the P-channel type MOS transistor of FIG. 1B; and

FIG. 16 is a graph showing the temporal change of the normalized variation of the drain-source current in the case where the gate-source voltage is set to −2.4 [V] for the P-channel type MOS transistor of FIG. 1B.

### DETAILED DESCRIPTION OF THE EMBODIMENTS

Preferred embodiments of the present invention will be explained below in detail with reference to the accompanying drawings.

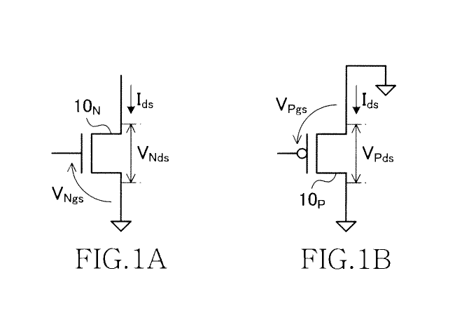

Each of FIGS. 1A and 1B shows a transistor corresponding to an embodiment of a manufacturing method according to the present invention. The transistor 10_{N} shown in FIG. 1A is an N-channel type MOS transistor and The transistor 10_{P} shown in FIG. 1B is a P-channel type MOS transistor. Hereinafter, as shown in FIGS. 1A and 1B, the drain-source voltage and gate-source voltage of the transistor 10_{N} are represented respectively as V_{Nds} and V_{Ngs}, and drain-source voltage and gate-source voltage of the transistor 10_{P} are represented respectively as V_{Pds} and V_{Pgs}. The drain-source current of each of the transistors is represented as I_{ds}. Although the present invention can be applied to both the N-channel type MOS transistor 10_{N} and P-channel type MOS transistor 10_{P}, the following descriptions are given taking the N-channel type MOS transistor 10_{N} as an example.

The transistor 10_{N} has a characteristic in which the absolute value of a threshold voltage Vₜₕ increases with use. This is called “hot carrier degradation” and it is known that a relationship represented by the following equation (1) is satisfied between the threshold voltage Vₜₕ and time t. In the following equation (1), ΔVₜₕ is the absolute value (=|Vₜₕ−Vₜₕ₀|) of the variation of the threshold voltage Vₜₕ from an initial value Vₜₕ₀ thereof. Further, n is a real number larger than 0 but smaller than 1. Thus, the increase rate of tⁿ to with time gradually decreases as time advances. Further, A is a constant number determined by device parameters of the transistor 10_{N}, voltages applied thereto and so on.

ΔVₜₕ=Atⁿ (1)

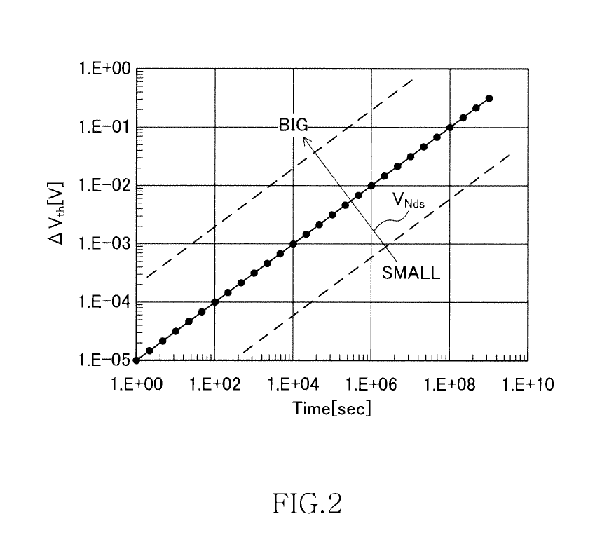

FIG. 2 is a graph plotting a change in a variation ΔVₜₕ with respect to time in the case where 0.5 and 10⁻⁵ are assigned respectively to n and A. In FIG. 2, both of vertical and horizontal axes are logarithmic axes.

As can be seen from equation (1) and FIG. 2, the variation ΔVₜₕ increases in proportion to the n-th power of time under the condition that the drain-source voltage V_{Nds} is constant. The variation ΔVₜₕ that has once increased does not decrease once again. Further, as shown in FIG. 2, since the constant A increases with respect to the drain-source voltage V_{Nds}, the variation ΔVₜₕ increases as the drain-source voltage V_{Nds} increases.

The hot carrier degradation as described above makes design of an N-channel type MOS transistor difficult, so that it is generally considered as an unfavorable characteristic. However, in the semiconductor device manufacturing method according to the present embodiment, this characteristic is aggressively utilized to thereby realize a transistor having a variety of threshold voltages Vₜₕ.

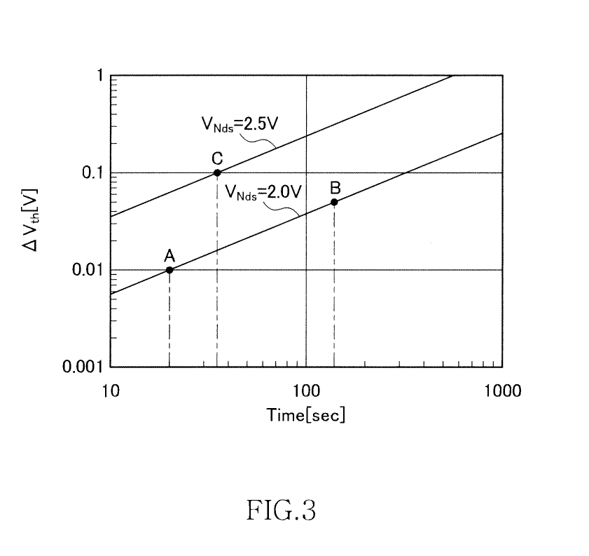

Description will be given with a concrete example taken. FIG. 3 is a graph showing a concrete example of a change in the variation ΔVₜₕ with respect to time. As shown in FIG. 3, when a drain-source voltage V_{Nds} of 2.0 [V] is applied for 20 seconds, the threshold voltage Vₜₕ increases by 0.01 [V] (ΔVₜₕ=0.01 [V], point A). Further, when a drain-source voltage V_{Nds} of 2.0 [V] is applied for 130 seconds, the threshold voltage Vₜₕ increases by 0.05 [V] (ΔVₜₕ=0.05 [V], point B). Further, when a drain-source voltage V_{Nds} of 2.5 [V] is applied for 35 seconds, the threshold voltage Vₜₕ increases by 0.1 [V] (ΔVₜₕ=0.1 [V], point C).

In other words, when a drain-source voltage V_{Nds} of 2.0 [V] is applied for 20 seconds, the threshold voltage Vₜₕ can be increased by 0.01 [V]. Similarly, when a drain-source voltage V_{Nds} of 2.0 [V] is applied for 130 seconds, the threshold voltage Vₜₕ can be increased by 0.05 [V], and when a drain-source voltage V_{Nds} of 2.5 [V] is applied for 35 seconds, the threshold voltage Vₜₕ can be increased by 0.1 [V].

In the present embodiment, a plurality of transistors are formed with a given constant threshold voltage Vₜₕ₀ initially. Then, for each transistor, the drain-source voltage V_{Nds} (stress voltage Vₛₜᵣₑₛₛ) corresponding to a target value of the threshold voltage Vₜₕ is applied by a time (application time period tₛₜᵣₑₛₛ) corresponding to the target value. As a result, a variety of threshold voltages Vₜₕ are realized.

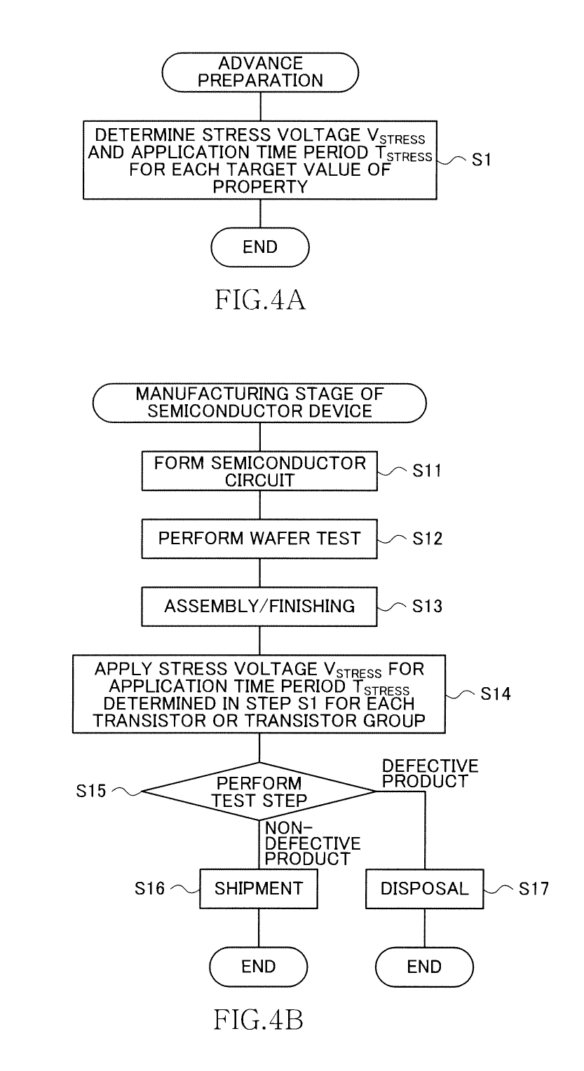

FIGS. 4A and 4B are views each showing a process flow of the semiconductor device manufacturing method according to the present embodiment.

As advance preparation, as shown in FIG. 4A, the stress voltage Vₛₜᵣₑₛₛ (drain-source voltage V_{Nds}) and application time period tₛₜᵣₑₛₛ thereof are determined for each target value of a characteristic (in this case, threshold voltage Vₜₕ) (step S1). The following table 1 represents the relationship among the target value of Vₜₕ, Vₛₜᵣₑₛₛ, and tₛₜᵣₑₛₛ of FIG. 3.

TABLE 1

| Target value of Vₜₕ | vₛₜᵣₑₛₛ (v_{Nds}) | tₛₜᵣₑₛₛ |
|---|---|---|
| Vₜₕ₀ + 0.01 [V] | 2.0 [V] | 20 sec |
| Vₜₕ₀ + 0.05 [V] | 2.0 [V] | 130 sec |
| Vₜₕ₀ + 0.1 [V] | 2.5 [V] | 35 sec |

In the processing of step S1, it is preferable to form a plurality of sample transistors designed with the same device parameters (conductivity type (P-type or N-type) of the semiconductor thin film, type and amount of impurities to be implanted into the channel region and source-drain region, channel length, gate width, gate film thickness, etc.) as those of the transistor 10_{N} set as a target of the processing according to the present embodiment. Then, preferably, different drain-source voltages V_{Nds} are applied to create a graph as shown in FIG. 3 and the stress voltage Vₛₜᵣₑₛₛ and application time period tₛₜᵣₑₛₛ thereof are determined based on this graph.

Alternatively, the application time period tₛₜᵣₑₛₛ may be determined first. In this case, preferably, different drain-source voltages V_{Nds} are applied to the plurality of sample transistors for the previously determined application time period tₛₜᵣₑₛₛ, and the stress voltage Vₛₜᵣₑₛₛ is determined based on the obtained result.

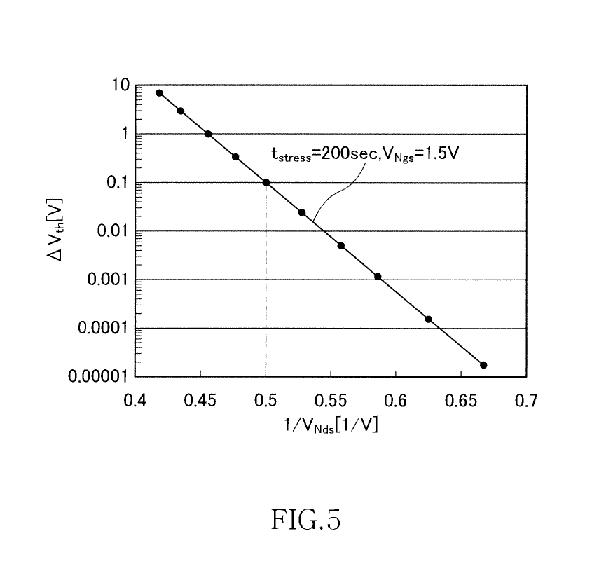

FIG. 5 is a graph showing the relationship between the drain-source voltage V_{Nds} and variation ΔVₜₕ in the case where the application time period tₛₜᵣₑₛₛ is set to 200 seconds. In this example, the gate-source voltage V_{Ngs} is set to 1.5 [V]. It can be understood from FIG. 5 that the stress voltage Vₛₜᵣₑₛₛ (drain-source voltage V_{Nds}) should be set to 2.0 [V](=1/0.5) when the target value of the threshold voltage Vₜₕ is set to Vₜₕ₀+0.1 [V] (variation ΔVₜₕ=0.1 [V]) under the assumption that the application time period tₛₜᵣₑₛₛ is set to 200 seconds.

In determining the stress voltage Vₛₜᵣₑₛₛ and application time period tₛₜᵣₑₛₛ, it is preferable to previously determine the gate-source voltage V_{Ngs} and operating temperature of the transistor 10_{N}.

In the case where the difference among the threshold voltages Vₜₕ of the transistors included in the semiconductor device is larger than a certain degree, the initial values Vₜₕ₀ of the threshold voltages as starting points may be made different from one another. In this case, it is preferable to determine the stress voltage Vₛₜᵣₑₛₛ and application time period tₛₜᵣₑₛₛ for each initial value Vₜₕ₀.

Further, there may a case where the stress voltage Vₛₜᵣₑₛₛ and application time period tₛₜᵣₑₛₛ for achieving a desired characteristic change depending on device parameters other than the type and amount of impurities to be implanted into the channel region, such as channel length, gate width, gate film thickness, type and amount of impurities to be implanted into the source-drain region. In such a case, it is preferable to determine the stress voltage V and stress application time period tₛₜᵣₑₛₛ for each combination of these device parameters.

Next, processing in the manufacturing stage will be described with reference to FIG. 4B. First, in the manufacturing stage, a semiconductor circuit is formed on a silicon substrate (semiconductor circuit formation process: step S11). In the case where a semiconductor device to be manufactured is a DRAM (Dynamic Random Access Memory), the semiconductor circuit formed here includes a memory cell array and its peripheral circuits.

A large number of transistors are included in the semiconductor circuit, and they vary in threshold voltage Vₜₕ (target value: second threshold voltage) depending on the use purpose. However, in the semiconductor circuit formation process, these transistors are designed with the same threshold voltage Vₜₕ₀ (first threshold voltage). This can be achieved by making the type and amount of impurities to be implanted into the channel region of each transistor the same. It should be noted that even if the amounts of impurities to be implanted respectively into channel regions are different from each other, the threshold voltages thereof can be substantially equal to each other. Further, the threshold voltage of a certain transistor can become equal to that of another transistor having a different channel width from the certain transistor. As a result, the threshold voltage Vₜₕ of each transistor thus formed assumes the initial value Vₜₕ₀. The initial value Vₜₕ₀ is required to be smaller than the target value of each transistor. This is because a change in the threshold voltage Vₜₕ caused by the hot carrier degradation brings about only rise in value.

Note that the initial values Vₜₕ₀ of all the transistors included in the semiconductor circuit need not always be the same at the stage of step S11. As described above, in the case where the difference among the threshold voltages Vₜₕ of the transistors is larger than a certain degree, the initial values Vₜₕ₀ may be made different from one another. Further, the device parameters such as channel length, gate width, gate film thickness, and type and amount of impurities to be implanted into the source-drain region may be made different for each transistor. Also in these cases, the stress voltage Vₛₜᵣₑₛₛ and application time period tₛₜᵣₑₛₛ are determined for each combination of the device parameters including the initial value Vₜₕ₀ in the processing of step S1, as described above.

After formation of the semiconductor circuit on the silicon substrate, a wafer test is performed (step S12). After that, an assembly/finishing process is performed (step S13). The assembly/finishing process includes dicing or separating the wafer into individual chips, packaging each of the chips, and the like.

Subsequently, a tester is used to selectively apply the stress voltage Vₛₜᵣₑₛₛ determined in the processing of step S1 to one or more transistors (that is, target transistors) in the formed semiconductor circuit for the determined application time period tₛₜᵣₑₛₛ (characteristic control process: step S14). The application of the stress voltage Vₛₜᵣₑₛₛ may be performed for each target transistor or may be performed collectively to a plurality of target transistors (transistor group) having the same target value of the characteristic. Through this control process, the characteristic of each target transistor may be controlled so as to exhibit a threshold voltage Vₜₕ equal to its target value (second threshold voltage).

Subsequently, a test process of the semiconductor circuit is performed (step S15). In the test process, various tests including the usual burn-in test are performed. In the burn-in test, a test voltage is applied to each transistor so as to find a part more likely to fail during normal operation after shipment. The test voltage applied in this process completely differs from the stress voltage used in the characteristic control process. The test voltage is applied simultaneously to the transistors including such transistors that are required to maintain an initial threshold voltage, and is applied only for such a short period of time that does not substantially influence the threshold voltage Vₜₕ of each transistor.

Semiconductor devices, which have been determined to be a non-defective product in the test process, are then shipped out after packing (step S16). At the time point of the shipment, each target transistor in the semiconductor device exhibits a threshold voltage Vₜₕ equal to its target value (second threshold voltage). The shipped out semiconductor devices are then transported to another factory and modularized as needed. Semiconductor devices determined to be a defective product in the test process are disposed of (step S17).

As described above, according to the semiconductor device manufacturing method of the present embodiment, the properties of the transistors can be made different from one another through the characteristic control process. As a result, a reduction in the manufacturing cost and manufacturing time can be achieved.

Further, the so-called “aging change” of the threshold voltage Vₜₕ can be suppressed in accordance with the embodiment of the present invention, as discussed below.

The aging change means such phenomenon in which a transistor represents changes in threshold voltage Vₜₕ little by little as the semiconductor device is running for a longer time period. For this reason, the threshold voltage/level of the transistor may become higher than an initial value in several years or more. Since the circuit design is performed based on the initial threshold of each transistor, undesired changes in threshold level would cause deterioration in operation speed or the like.

As is apparent from the equation (1) including the condition of 0<n<1, the increase rate of the threshold voltage Vₜₕ with time gradually decreases (and thus becomes saturated). In other words, by making a transistor have in advance a relatively large ΔVₜₕ, the transistor represents less change in threshold level even after long time operation.

As described above with reference to FIG. 4B, the present embodiment can equivalently give the transistor substantial variation ΔVₜₕ in threshold through the characteristic control process before shipment. In other words, “pseudo” aging change is already generated. Thus, the aging change of the transistor that has passed through the characteristic control process is smaller than that of the transistor that has not passed through the characteristic control process, resulting in suppressing the aging change after shipment.

The description has been made focusing on the transistor 10_{N} (FIG. 1A) which is an N-channel type MOS transistor. Also in the case where the transistor 10_{P} (FIG. 1B) which is a P-channel type MOS transistor is used, the same effect can be obtained by performing the same characteristic control process. However, in the case of the P-channel type MOS transistor, not the hot carrier degradation but a phenomenon called NBTI (Negative Bias Temperature Instability) is utilized. Like the hot carrier degradation, the NBTI is a phenomenon in which the threshold voltage Vₜₕ of the transistor 10_{P} increases with use. The NBTI is the same as the hot carrier degradation in that the variation ΔVₜₕ is represented by the equation (1) but differs the hot carrier degradation in that the constant number A is dependent not on the drain-source voltage V_{Pds} but to the gate-source voltage V_{Pgs}. Thus, the stress voltage Vₛₜᵣₑₛₛ for controlling the threshold voltage Vₜₕ of the transistor 10_{P} is not the drain-source voltage V_{Pds} but the gate-source voltage V_{Pgs}.

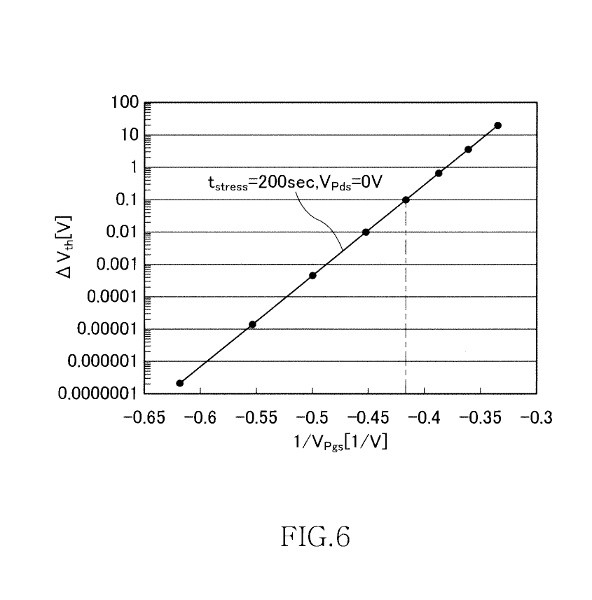

FIG. 6 is a graph showing the relationship between the gate-source voltage V_{Pgs}, and variation ΔVₜₕ in the case where the application time period tₛₜᵣₑₛₛ is set to 200 seconds. Here, the drain-source voltage V_{Pds} is set to 0 [V]. As is understood from a comparison between FIGS. 5 and 6, the transistor 10_{N} (FIG. 5) and transistor 10_{P} (FIG. 6) exhibit the same characteristic except for the type of the stress voltage and its sign plotted on the horizontal axis. It can be understood from FIG. 6 that the stress voltage Vₛₜᵣₑₛₛ (gate-source voltage V_{Pgs},) should be set to −2.4 [V] (≅1/(−0.42)) when the target value of the threshold voltage Vₜₕ is set to Vₜₕ₀+0.1 [V] under the assumption that the application time period tₛₜᵣₑₛₛ is set to 200 seconds.

Further, according to the semiconductor device manufacturing method of the present embodiment, the drain-source currents I_{ds} of the transistor 10_{N} and transistor 10_{P} can be controlled in the same manner as in the case of the threshold voltage Vₜₕ. This point will be described later.

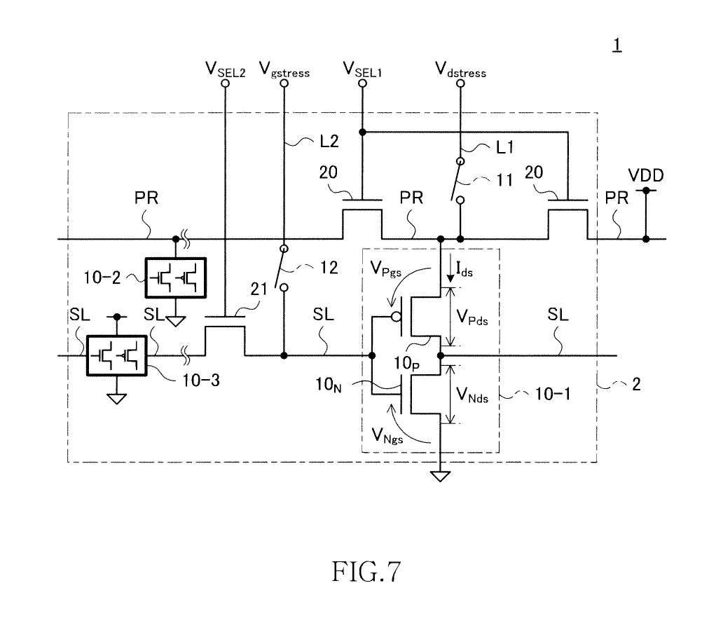

FIG. 7 is a view showing a circuit configuration of a semiconductor device 1 corresponding to another embodiment of the present invention. As shown, the semiconductor device 1 includes a semiconductor circuit 2 having a CMOS inverter 10-1 constituted by the transistors 10_{N} and 10_{P}. The semiconductor device 1 may be a DRAM, and the CMOS inverter 10-1 may be a word driver for driving a word line formed in the DRAM. The semiconductor circuit 2 is configured to be able to control the threshold voltages Vₜₕ of the transistors 10_{N} and 10_{P} through the above characteristic control process. In other words, the transistors 10_{N} and 10_{P} are required to have a higher threshold level than other transistors.

As shown in FIG. 7, the semiconductor circuit 2 has circuits 10-2 and 10-3 each having N-channel type MOS transistor or P-channel type transistor, or both of them in addition to the CMOS inverter 10-1. The internal configuration of each of the circuits 10-2 and 10-3 is not especially limited and, for example, the circuits 10-2 and 10-3 may be a CMOS inverter configuration like the CMOS inverter 10-1. Hereinafter, it is assumed that the N-channel type MOS transistors and P-channel type transistors in the circuits 10-2 and 10-3 as finished pieces have different threshold voltages Vₜₕ from those of the transistors 10_{N} and 10_{P}, respectively. However, the transistors in the circuits 10-2 and 10-3 are designed and formed so as to have the same in threshold level as the transistors 10_{N} and 10_{P} at the end of the semiconductor circuit formation process.

The CMOS inverter 10-1, circuit 10-2, and circuit 10-3 are connected at the respective one end to a ground line to which ground potential is supplied. The other end (for example, the source of the transistor 10_{P}) of the CMOS inverter 10-1 and that of the circuit 10-2 are connected in common to a power rail PR to which a power supply potential VDD higher than the ground potential is supplied. The circuit 10-3 is connected at its other end to another power rail PR. The input/output terminals of the CMOS inverter 10-1 and circuit 10-3 are connected signal lines SL correspondingly. In the case where the CMOS inverter 10-1 constitutes a part of a word driver, one of the signal lines SL may be a word line.

An N-channel type MOS transistor 20 serves as a switch and is inserted between a portion of the power rail PR connected with the CMOS inverter 10-1 and another portion connected with the circuit 10-2. The transistor 20 may be of another channel type such as P-channel. The transistor 20 is provided for the purpose of preventing the stress voltage V_{dstress} to be described later from being applied to the circuit 10-2 which is not a controlled object of the characteristic control process when the stress voltage V_{dstress} is applied to the power rail PR in order to control the characteristic of the transistor 10_{N} in the process. Thus, the transistor 20 needs to be turned OFF (non-conductive) when the stress voltage V_{dstress} is applied and turned ON (conductive) at the rest of the time. Such ON/OFF control is achieved by supplying voltage V_{SEL1} to the gate of the transistor 20 from an external device (tester).

One more transistor 20 is provided in the device 1 shown in FIG. 7, which is inserted between a portion of the power rail PR connected with the CMOS inverter 10-1 and another portion connected with other circuits such as the circuit 10-2. The voltage V_{SEL1} is supplied in common to the gates of the respective transistors 20.

A N-channel type MOS transistor 21 serves as a switch and is inserted between a portion of the signal line SL connected with the CMOS inverter circuit 10-1 and another portion connected with the circuit 10-3. The transistor 21 may be of another channel type such as P-channel. The transistor 21 is provided for the purpose of preventing the stress voltage V_{gstress} to be described later from being applied to the circuit 10-3 when the stress voltage V_{gstress} is applied to the signal line SL in order to control the characteristic of the transistor 10_{P} in the characteristic control process, because the circuit 10-3 is not a controlled object of the characteristic control process. Thus, the transistor 21 needs to be turned OFF (non-conductive) when the stress voltage V_{gstress} is applied and turned ON (conductive) at the rest of the time. Such ON/OFF control is achieved by supplying voltage V_{SEL2} to the gate of the transistor 21 from an external device (tester).

The transistors 20 and 21 may be substituted by anti-fuse elements. The anti-fuse element is non-conductive in the initial state and irreversibly turned conductive when a voltage of a predetermined level or more is applied thereto. In this case, the voltages V_{SEL1} and voltage V_{SEL2} are supplied from an external device (tester) in order to make a non-conductive anti-fuse element conductive.

One end of a first voltage input line L1 is connected to between a portion of the power rail PR to which the transistor 20 is inserted and another portion connected with the CMOS inverter 10-1. A test pad (not shown) is formed at the other end of the first voltage input line L1. Through the test pad, the stress voltage V_{dstress} is supplied from an external device (tester). A switch 11 is inserted between one end and the other end of the first voltage input line L1.

One end of a second voltage input line L2 is connected to between a portion of the signal line SL to which the transistor 21 is inserted and another portion connected with the CMOS inverter 10-1. A test pad (not shown) is formed at the other end of the second voltage input line L2. Through the test pad, the stress voltage V_{gstress} is supplied from an external device (tester). A switch 12 is inserted between one end and the other end of the second voltage input line L2.

Although not shown, the switches 11 and 12 can be ON/OFF controlled from an external device (tester) like the transistor 20. Concretely, as the switches 11 and 12, a transistor such as the N-channel MOS transistor or a fuse element may be used. The fuse element is conductive in the initial state and irreversibly turned non-conductive when a voltage of a predetermined level or more is applied thereto.

Hereinafter, a procedure of controlling the threshold voltages Vₜₕ of the transistors 10_{N} and 10_{P} in the semiconductor device 1 having the above circuit configuration will be described also with reference once again to FIGS. 4A and 4B.

First, based on the target value of the threshold voltage Vₜₕ, the stress voltages Vₛₜᵣₑₛₛ to be applied to the transistors 10_{N} and 10_{P} and application time periods tₛₜᵣₑₛₛ are determined (step S1). The details of the determination method are as described above. Then, the semiconductor device 1 shown in FIG. 7 is formed on a semiconductor substrate (step S11). At this stage, the absolute values of the threshold voltages Vₜₕ₀ of the transistors 10_{N} and 10_{P} are smaller than the absolute values of the respective target values. After formation of the semiconductor device 1 on the semiconductor substrate, the wafer test (step S12) and assembly/finishing process (step S13) are sequentially performed.

Subsequently, the characteristic control process is performed (step S14). Specifically, the stress voltages Vₛₜᵣₑₛₛ are applied to each of the transistors 10_{N} and 10_{P} for the application time periods tₛₜᵣₑₛₛ determined in step S1. As described later in detail, in the characteristic control process, the stress voltage Vₛₜᵣₑₛₛ is not applied to the circuits 10-2 and 10-3 but only to the transistors 10_{N} and 10_{P}. Thus, after completing the characteristic control process, the threshold voltage Vₜₕ of the transistor 10_{N} and threshold voltage Vₜₕ of the N-channel type MOS transistors in the circuit 10-2 and circuit 10-3 differ from each other. Similarly, the threshold voltage Vₜₕ of the transistor 10_{P} and threshold voltage Vₜₕ of the P-channel type MOS transistors in the circuit 10-2 and circuit 10-3 differ from each other.

Hereinafter, the processing of step S14 (characteristic control process) will be described in detail. In the following description, the processing of the transistor 10_{N} is performed in advance of the processing of the transistor 10_{P}. The processing order may be reversed.

First, by controlling from the tester, the voltage V_{SEL1} and voltage V_{SEL2} are made non-active (low). As a result, both the transistors 20 and 21 are made non-conductive. In the case where the transistors 20 and 21 are anti-fuse elements, this operation is not necessary. Then, the stress voltage V_{dstress} is applied from the tester to the first voltage input line L1, together with switching on the switch 11 by controlling from the tester. At the same time, the stress voltage V_{gstress} is applied from the tester to the second voltage input line L2, together with switching on the switch by controlling from the tester. As a result, the drain-source voltage V_{Nds} of the transistor 10_{N} becomes equal to [V_{dstress}−V_{Pds}]. V_{Pds} is the drain-source voltage of the transistor 10_{P}.

Concrete values of the stress voltage V_{dstress} and stress voltage V_{gstress} are determined such that the drain-source voltage V_{Nds}=[V_{dstress}−V_{Pds}] of the transistor 10_{N} is equal to the stress voltage Vₛₜᵣₑₛₛ determined for the transistor 10_{N}. In practice, it is suitable to obtain optimum values of the stress voltage V_{dstress} and stress voltage V_{gstress} with the use of a sample CMOS inverter having the same configuration as an actual circuit.

The optimum values of the stress voltage V_{dstress} and stress voltage V_{gstress} will be described using concrete numerical examples. In what follows, assume that 2.0 [V] is required as the stress voltage Vₛₜᵣₑₛₛ to be applied to the transistor 10_{N}. Note that the parameters explained below need to be determined so that both the transistors 10_{N} and 10_{P} is turned ON throughout applying the stress voltage Vₛₜᵣₑₛₛ to the transistor 10_{N}. This is because the stress voltage Vₛₜᵣₑₛₛ being the drain-source voltage V_{Nds} is applied to the transistor 10_{N} through the transistor 10_{P}. Here, assuming that the stress voltage V_{gstress} is 1.5 [V], the gate-source voltage V_{Ngs} of the transistor 10_{N} is 1.5 [V], while the gate-source voltage V_{Pgs} and drain-source voltage V_{Pds} depend on the drain voltage of the transistor 10_{P}. Concrete values of the gate-source voltage V_{Pgs} and drain-source voltage V_{Pds} can be obtained in a simulation with a concrete value of the drain voltage of the transistor 10_{P}. In one example, assuming that the drain voltage of the transistor 10_{P} is 2.5 [V], the gate-source voltage V_{Pgs} and drain-source voltage V_{Pds} is −1.0 [V] and 0.5 [V], respectively. Accordingly, in this case, the drain-source voltage V_{Nds} of the transistor 10_{N} becomes 2.0 [V] (=2.5 [V]−0.5 [V]). Since this value 2.0 [V] coincides with the desired stress voltage mentioned above, it is understood the stress voltage V_{dstress} should be determined so that the drain voltage of the transistor 10_{P} is 2.5 [V] in this case. Typically, since the drain voltage of the transistor 10_{P} is substantially the same as the stress voltage V_{dstress}, the preferred stress voltage V_{dstress} is 2.5 [V].

Since the gate-source voltage V_{Pgs} of the transistor 10_{P} is equal to the difference [V_{gstress}−V_{dstress}] between the stress voltage V_{gstress} and stress voltage V_{dstress}, it is preferable that the absolute value of [V_{gstress}−V_{dstress}] is adjusted not to be excessive so as not to have a major influence on the threshold voltage Vₜₕ of the transistor 10_{P}.

After elapse of the application time period tₛₜᵣₑₛₛ from the turning ON of the switch 11, the threshold voltage Vₜₕ of the transistor 10_{N} becomes equal to the target value. At this time point, the characteristic control process for the transistor 10_{N} is completed.

Then, by controlling from the tester, the stress voltage V_{dstress} and stress voltage V_{gstress} are changed. Concrete values of the stress voltage V_{dstress} and stress voltage V_{gstress} after the change are determined such that the gate-source voltage V_{Pgs}=[V_{gstress}−V_{dstress}] of the transistor 10_{P} is equal to the stress voltage Vₛₜᵣₑₛₛ determined for the transistor 10_{P}.

More concretely, the V_{dstress} is set to 0 [V]. In this case, making the V_{gstress} equal to the Vₛₜᵣₑₛₛ makes it possible to apply an adequate stress voltage Vₛₜᵣₑₛₛ to the transistor 10_{P}. It should be noted that the transistor 20 may not be switched off in case the V_{dstress} is set to 0 [V]. This is because no problems would occur even if 0 [V] is applied to the circuit 10-2 through the power rail PR.

The optimum values of the stress voltage V_{dstress} and stress voltage V_{gstress} will be described using numerical examples. In the case where the target value of the threshold voltage Vₜₕ is set to [Vₜₕ₀+0.1 [V]] (variation ΔVₜₕ=0.1 [V]) in the example of FIG. 6, the stress voltage Vₛₜᵣₑₛₛ determined in step S1 is −2.4 [V]. This is achieved by setting the stress voltage V_{dstress} and stress voltage V_{gstress} to 0 [V] and −2.4 [V], respectively.

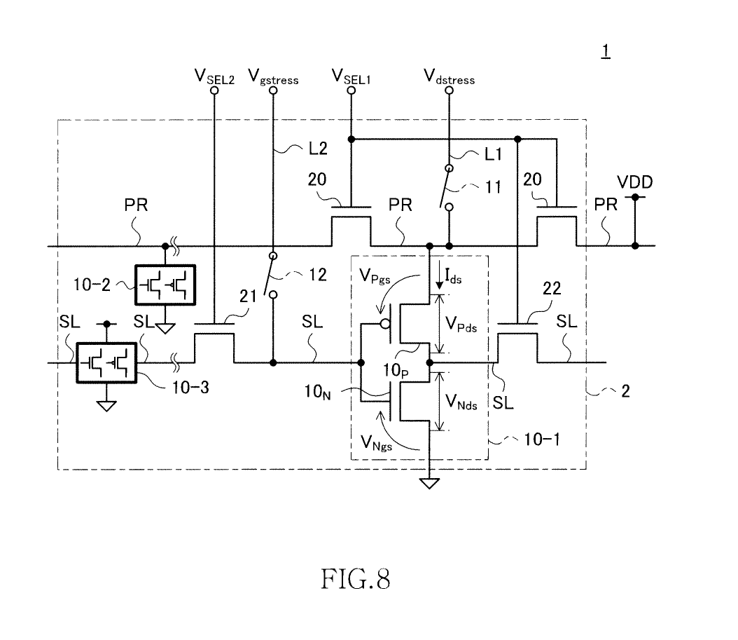

It should be noted that setting the stress voltage V_{dstress} and stress voltage V_{gstress} to 2.4 [V] and 0 [V], respectively, can also achieve the above stress voltage Vₛₜᵣₑₛₛ (=−2.4 [V]). Since the transistor 10_{N} becomes OFF state in this case, the voltage of the signal line SL may increase up to about 2.4 [V]. If this voltage increase needs to be avoided, it is helpful to add a transistor 22 to the output terminal of the CMOS inverter 10-1 as shown in FIG. 8, and to control the ON/OFF state of the transistors 20 and 22 simultaneously.

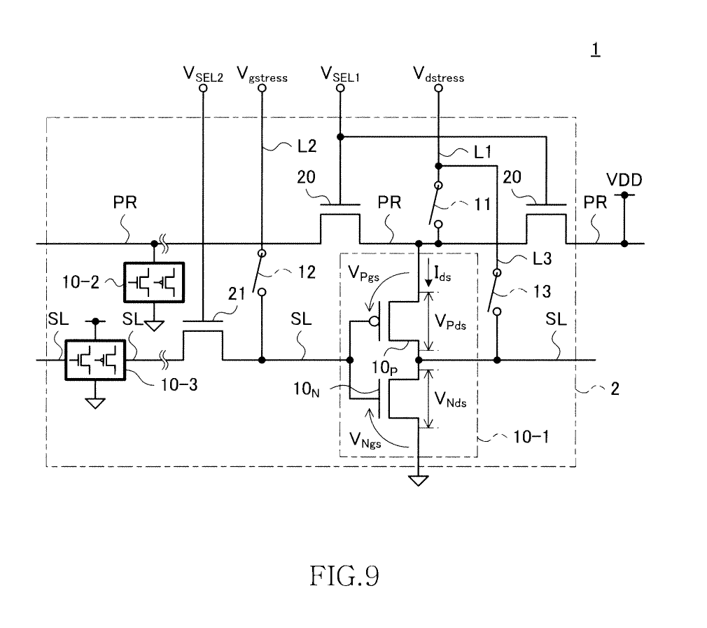

In FIG. 6, the drain-source voltage V_{Pds} is set to 0 [V]. This is not essential in terms of the characteristic control. However, from a viewpoint that it is not preferable that the voltage value of the drain-source voltage V_{Pds} becomes unsettled, a line L3 connecting the first voltage input line L1 and signal line SL may be provided as shown in FIG. 9. The drain-source voltage V_{Pds} can be set to 0 [V] by providing a switch 13 along the line L3 and switching on the switch 13 when the characteristic control process of the transistor 10_{P} is performed. The switch 13 is turned OFF at the rest of the time.

Returning to FIG. 4, after completion of the characteristic control process (step S14), the test process of the semiconductor circuit is performed (step S15). The details of the test process are as described above. The test voltage used in the burn-in test is applied not only to the transistors 10_{N} and 10_{P} but also to the transistors in the circuits 10-2 and 10-3.

After completion of the test process (step S15), a shipment process (step S16) or a disposal process (step S17) is performed depending on a result of the test process, whereby a series of processes are completed.

As described above, according to the manufacturing method of the present embodiment, the properties of the N-channel type MOS transistor and P-channel type MOS transistor constituting the CMOS inverter can individually be controlled.

The above description has been made focusing on one semiconductor circuit 2. In the case where the semiconductor device 1 has a plurality of semiconductor circuits 2, the characteristic control process can be performed in parallel for the plurality of semiconductor circuits 2.

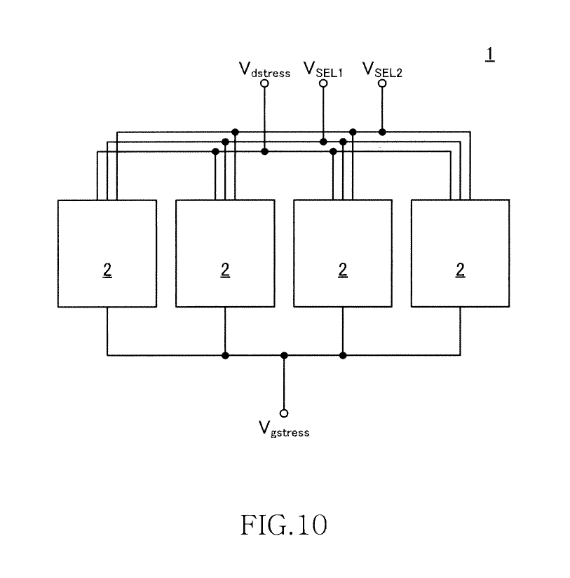

FIG. 10 shows a circuit configuration of the semiconductor device 1 having the plurality of semiconductor circuit 2 each corresponding to the embodiment of the present invention. As shown, in this semiconductor device 1, the stress voltages V_{dstress} and V_{gstress} and voltages V_{SEL1} and V_{SEL2} are supplied in parallel to the respective semiconductor circuits 2. Further, although not shown, the control signals of the switches 11 to 13 are also supplied in parallel to the respective semiconductor circuits 2. As a result, is possible to apply the stress voltage Vₛₜᵣₑₛₛ to the selected one or more transistors out of the transistors in the semiconductor devices 2 for the application time period tₛₜᵣₑₛₛ.

Hereinafter, an example in which the drain-source current I_{ds} of each of the transistors 10_{N} and 10_{P} is set as a control target will be described in detail.

First, drain-source current characteristics of the transistors 10_{N} and 10_{P} shown in FIG. 1 will be described. Contrary to the threshold voltage Vₜₕ, the drain-source current I_{ds} has a characteristic of decreasing with use. This phenomenon is also caused by the hot carrier degradation for the N-channel MOS transistor and by the NBTI for the P-channel MOS transistor.

A relationship represented by the following equation (2) is satisfied between the drain-source current I_{ds} and time t. In the following equation (2), ΔI_{ds} is the absolute value of the variation of the drain-source current I_{ds} from its initial value I_{ds0} (ΔI_{ds}=|I_{ds}−I_{ds0}|). ΔI_{ds}/I_{ds0} in the left-hand side means an amount (a normalized variation) obtained by normalizing the variation ΔI_{ds} with the initial value I_{ds0}. Further, n is a real number larger than 0 but smaller than 1, and B is a constant number represented by equation (3). C₁ and BB in the following equation (3) are constant numbers determined by a test. Vds is the drain-source voltage of each of the transistors 10_{N} and 10_{P}.

$$\begin{matrix}\frac{Δ {I}_{ds}}{{I}_{ds 0}} = {Bt}^{n} & ( 2 ) \\ B = {C}_{1} exp ( - \frac{BB}{{V}_{ds}} ) & ( 3 )\end{matrix}$$

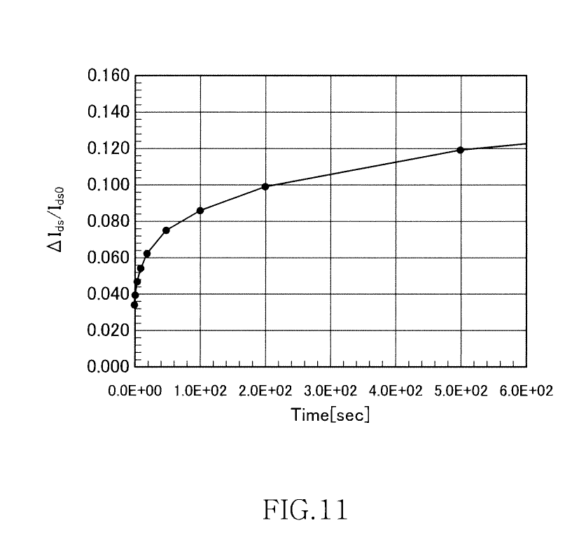

FIG. 11 is a graph plotting an example of the temporal change of the normalized variation ΔI_{ds}/I_{ds0} indicated in equation (2). As can be seen from equation (2) and FIG. 11, the normalized variation ΔI_{ds}/I_{ds0} has the same characteristic as that of the threshold voltage Vₜₕ. That is, the normalized variation ΔI_{ds}/I_{ds0} increases in proportion to the n-th power of time. Further, the increase rate of normalized variation ΔI_{ds}/I_{ds0} with time gradually decreases as the normalized variation ΔI_{ds}/I_{ds0} increases.

Thus, by performing the same characteristic control process as that for the threshold voltage Vₜₕ, the drain-source current I_{ds} can be increased, and the characteristics of the plurality of transistors formed in the semiconductor device can be made different from one another by the characteristic control process. In addition, the aging change of the drain-source current I_{ds} can also be suppressed.

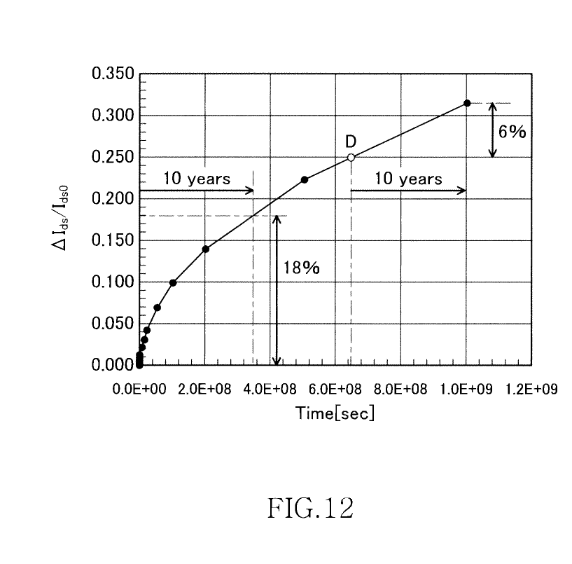

The suppression of the aging change will be described using a concrete example. FIG. 12 shows an example of the temporal change of the normalized variation ΔI_{ds}/I_{ds0} assuming that a typical operating voltage continues to be applied to the transistor. As shown, the normalized variation ΔI_{ds}/I_{ds0} increases from 0 to 0.180 in about ten years from the start of the voltage application. This means that the drain-source current I_{ds} has increased by 18% in this ten years. However, in ten years from, e.g., point D (normalized variation ΔI_{ds}/I_{ds0}=0.250), the increase of the normalized variation ΔI_{ds}/I_{ds0} stops at 0.060 (6%). Thus, increasing the normalized variation ΔI_{ds}/I_{ds0} up to 0.250 by the characteristic control process at manufacturing time makes it possible to suppress the aging change of the drain-source current I_{ds} over ten years by 12%.

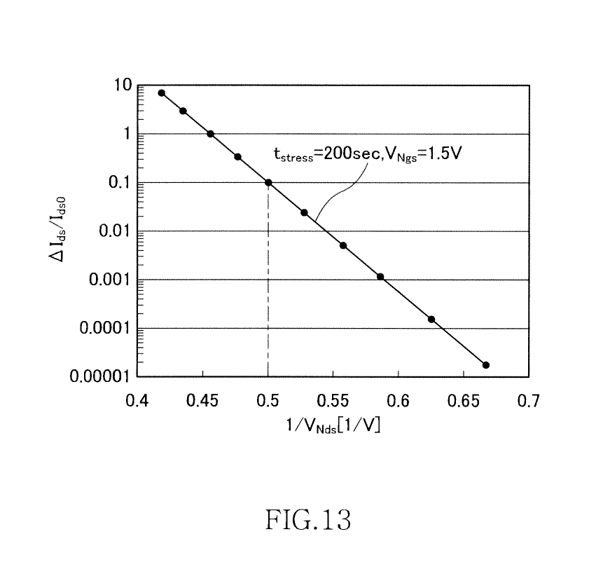

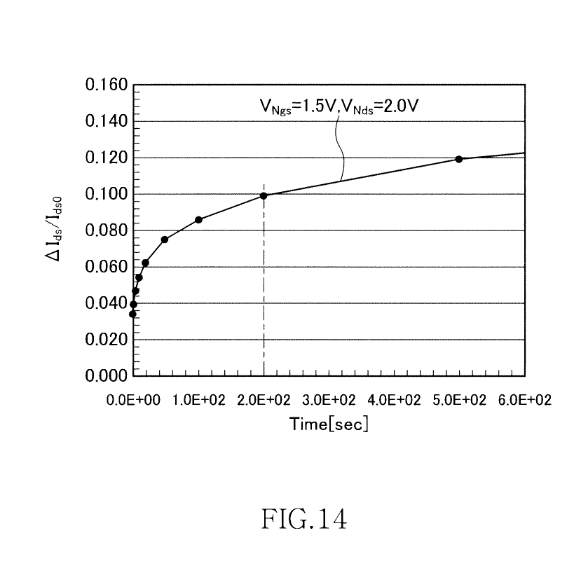

FIG. 13 is a graph showing the relationship between the drain-source voltage V_{Nds} and the normalized variation ΔI_{ds}/I_{ds0} in the case where the application time period tₛₜᵣₑₛₛ is set to 200 seconds for the transistor 10_{N} (N-channel type MOS transistor) of FIG. 1A. FIG. 14 is a graph showing the temporal change of the normalized variation ΔI_{ds}/I_{ds0} in the case where the drain-source voltage V_{Nds} is set to 2.0 [V] for the transistor 10_{N}. In either case, the gate-source voltage V_{Ngs} is set to 1.5 [V]. As can be understood from FIGS. 13 and 14, it is possible to reduce the drain-source current I_{ds} of the transistor 10_{N} to [I_{ds}−0.1I_{ds0}] through the characteristic control process by setting the application time period tₛₜᵣₑₛₛ and stress voltage Vₛₜᵣₑₛₛ to 200 seconds and 2.0 [V], respectively.

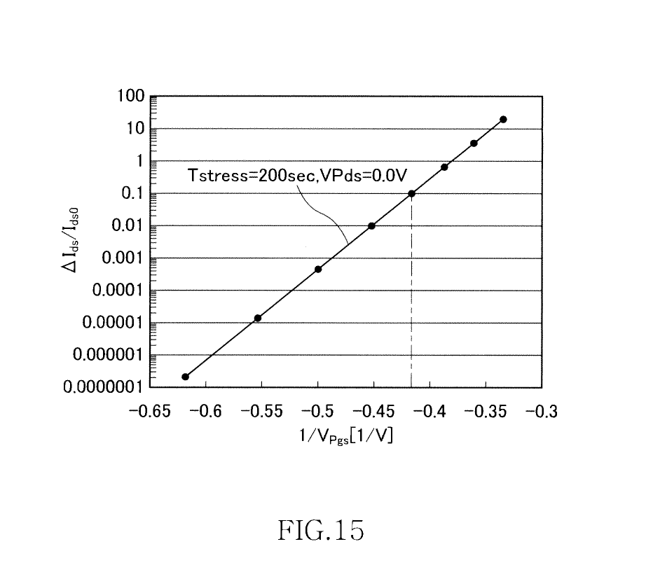

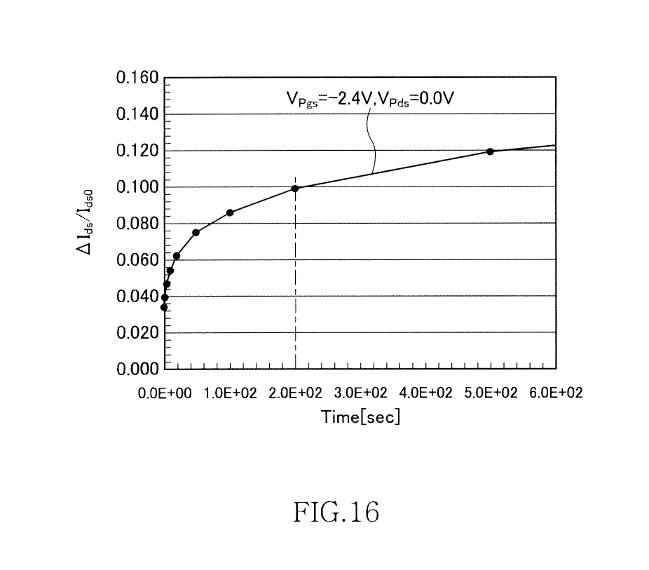

FIG. 15 is a graph showing the relationship between the gate-source voltage V_{Pgs} and normalized variation ΔI_{ds}/I_{ds0} in the case where the application time period tₛₜᵣₑₛₛ is set to 200 seconds for the transistor 10_{P} (P-channel type MOS transistor) of FIG. 1B. FIG. 16 is a graph showing the temporal change of the normalized variation ΔI_{ds}/I_{ds0} in the case where the gate-source voltage V_{Pgs} is set to −2.4 [V] for the transistor 10_{P}. In either case, the drain-source voltage V_{Pds} is set to 0.0 [V]. As can be understood from FIGS. 15 and 16, it is possible to reduce the drain-source current I_{ds} of the transistor 10_{P} to [I_{ds}−0.1I_{ds0}] through the characteristic control process by setting the application time period tₛₜᵣₑₛₛ and stress voltage Vₛₜᵣₑₛₛ (gate-source voltage V_{Pgs}) to 200 seconds and −2.4 [V], respectively.

As described above, according to the manufacturing method of the present embodiment, the drain-source current I_{ds} of each of the transistors 10_{N} and 10_{P} can also be controlled as with the threshold voltage Vₜₕ.

It is apparent that the present invention is not limited to the above embodiments, but may be modified and changed without departing from the scope and spirit of the invention.

For example, although only the case where the threshold voltage Vₜₕ is controlled has been described in an explanation about FIG. 7, it is of course possible to control the drain-source current I_{ds} of each transistor by the same configuration and processing.

Further, in FIG. 7, only one CMOS inverter 10-1 is set as a controlled object; however, in the case where another CMOS inverter connected in parallel to the CMOS inverter 10-1 exists in the semiconductor circuit 2, these CMOS inverters may be controlled simultaneously.

Further, the process sequence shown in FIG. 4B may be changed so that the characteristic control process (step S14) is performed before the wafer test (step S12). In case where the anti-fuse elements are used as substitute for the transistors 20 to 22, it is necessary to break down the anti-fuse elements after completing the characteristic control process (step S14). Since the above-mentioned revised process sequence enables the anti-fuse elements to be broken down in the wafer test (step S12) or the assembly/finishing process (step S13) with the other anti-fuse elements, the total time required for conducting the manufacturing method according to the present invention is reduced. In addition, in case where the anti-fuse elements are used as substitute for the transistors 20 to 22, each of the switches 11 to 13 is usually composed of fuse element. And, the above-mentioned revised process sequence enables the fuse elements to be cut in the wafer test (step S12) or the assembly/finishing process (step S13) with the other fuse elements, as is the case in the anti-fuse elements. Therefore, the total time required for conducting the manufacturing method according to the present invention is reduced also from this point of view.

Further, although a DRAM is taken as an example of the application of the present invention, it should be noted that the present invention is applicable to semiconductor devices of other types including various semiconductor storage device other than the DRAM.

What is claimed is:

1. A method comprising:
forming a semiconductor circuit including a first transistor with a first threshold voltage and a first drain-source current;
applying a stress voltage to the first transistor to make at least one of a change from the first threshold voltage to a second threshold voltage and a change from the first drain-source current to a second drain-source current; and
shipping the semiconductor circuit while the first transistor is presenting one of the second threshold voltage and the second drain-source current.

2. The method as claimed in claim 1, wherein
the semiconductor circuit further includes a second transistor with at least one of the first threshold voltage and the first drain-source current, and
the stress voltage is applied to the first transistor while the second transistor being free from being applied with the stress voltage.

3. The method as claimed in claim 1, wherein
the stress voltage is applied to change the first threshold voltage to the second threshold voltage, the second threshold voltage being larger in absolute value than the first threshold voltage.

4. The method as claimed in claim 1, wherein
the stress voltage is applied to change the first drain-source current to the second drain-source current, the second drain-source current being lower in aging rate than the first drain-source current.

5. The method as claimed in claim 1, further comprising performing a burn-in test on the semiconductor circuit after applying the stress voltage and before shipping the semiconductor circuit.

6. A method comprising:
forming a semiconductor circuit including first and second transistors that are designed to equal in a certain characteristic to each other;
applying a stress voltage to the first transistor while releasing the second transistor from being applied with the stress voltage so as to make the first and second transistors differ in the certain characteristic from each other; and
applying a test voltage to each of the first and second transistors to test circuit functions of the first and second transistors.

7. The method as claimed in claim 6, wherein the certain characteristic includes at least one of a threshold voltage and a drain-source current.

8. The method as claimed in claim 6, wherein
each of the first and second transistors is of an N-channel type, and
the stress voltage is applied between a drain and a source of the first transistor.

9. The method as claimed in claim 6, wherein
each of the first and second transistors is of a P-channel type, and
the stress voltage is applied between a gate and a source of the first transistor.

10. The method as claimed in claim 6, wherein
the certain characteristic includes a threshold voltage, and
the stress voltage is applied up to the threshold voltage of the first transistor being changed from a first level to a second level.

11. A method comprising:
forming in a semiconductor wafer a plurality of chips each including first and second transistors and a control element; and
applying a stress voltage to each of the chips so that the stress voltage is conveyed to the first transistor while making the control element block the stress voltage from being conveyed to the second transistor, the first transistor thereby presenting a threshold voltage that is different from the second transistor.

12. The method as claimed in claim 11, further comprising testing each of the chips, the testing being performed before the applying the stress voltage.

13. The method as claimed in claim 11, further comprising testing each of the chips, the testing being performed after the applying the stress voltage.

14. The method as claimed in claim 12, further comprising dicing the semiconductor wafer to separate the chips from one another, the dicing being carried out after the testing and before the applying the stress voltage.

15. The method as claimed in claim 13, further comprising dicing the semiconductor wafer to separate the chips from one another, the dicing being carried out after the testing.

16. The method as claimed in claim 12, further comprising performing a burn-in test on each of the chips.

17. The method as claimed in claim 13, further comprising performing a burn-in test on each of the chips.
